(19) United States
(12) Patent Application Publication
(10) Pub. No.: US 2024/0413077 A1
(43) Pub. Date: Dec. 12, 2024

(54) SEMICONDUCTOR DEVICE AND DISTANCE MEASURING DEVICE

(71) Applicant: SONY SEMICONDUCTOR SOLUTIONS CORPORATION, KANAGAWA (JP)

(72) Inventor: TAKANORI OKAMURA, KANAGAWA (JP)

(21) Appl. No.: 18/701,721

(22) PCT Filed: Sep. 20, 2022
(86) PCT No.: PCT/JP2022/034904

§ 371 Date: Apr. 16, 2024

(30) Foreign Application Priority Data
Oct. 26, 2021 (JP) 2021-174956

(51) Int. Cl. H01L 23/522; G01S 17/10; H01L 23/538; H01L 25/16; H01L 31/107; H01S 5/183

(52) U.S. Cl. CPC H01L 23/5227; G01S 17/10; H01L 23/5389; H01L 25/167; H01L 31/107; H01S 5/183

(57) ABSTRACT

Provided are a semiconductor device and a distance measuring device capable of reducing parasitic inductance between a plurality of substrates. The semiconductor device of the present disclosure includes: a first substrate including a semiconductor element, a first electrode provided on the semiconductor element, and a second electrode extending in a first direction in plan view; a second substrate including a wiring extending in a second direction parallel to the first direction in plan view, a transistor electrically connected to the wiring, and a capacitor electrically connected to the wiring; a first connection portion electrically connecting the first electrode and the second substrate; and a second connection portion electrically connecting the second electrode and the second substrate.

### TECHNICAL FIELD

The present disclosure relates to a semiconductor device and a distance measuring device.

### BACKGROUND ART

As a type of semiconductor laser, a surface-emitting laser such as a vertical cavity surface emitting laser (VCSEL) is known. In general, in a light emitting device utilizing a surface emitting laser, a plurality of light emitting elements is provided in a two-dimensional array on a front surface or a back surface of a substrate.

### CITATION LIST

### Patent Document

Patent Document 1: Japanese Unexamined Patent Application Publication No. 2004-526194
Patent Document 2: Japanese Patent Application Laid-Open No. 2003-045989

### SUMMARY OF THE INVENTION

### Problems to be Solved by the Invention

The light emitting device is configured by, for example, combining a laser diode (LD) chip including a light emitting element and a laser diode driver (LDD) substrate that drives the light emitting element. In this case, a parasitic inductance is generated between the LD chip and the LDD substrate, and the parasitic inductance may adversely affect the operation of the light emitting device. Such a problem can similarly occur in a case where a semiconductor device other than the light emitting device is manufactured by combining a plurality of substrates.

Therefore, the present disclosure provides a semiconductor device and a distance measuring device capable of reducing parasitic inductance between a plurality of substrates.

### Solutions to Problems

A semiconductor device according to a first aspect of the present disclosure includes: a first substrate including a semiconductor element, a first electrode provided on the semiconductor element, and a second electrode extending in a first direction in plan view; a second substrate including a wiring extending in a second direction parallel to the first direction in plan view, a transistor electrically connected to the wiring, and a capacitor electrically connected to the wiring; a first connection portion electrically connecting the first electrode and the second substrate; and a second connection portion electrically connecting the second electrode and the second substrate. As a result, for example, by bringing the current path in the second electrode and the current path in the wiring close to each other, the parasitic inductance between the first substrate and the second substrate can be reduced.

Furthermore, in the first aspect, the semiconductor element may be a light emitting element. As a result, for example, the parasitic inductance of the light emitting device can be reduced.

In addition, in the first aspect, the second electrode may have a shape surrounding the first electrode in plan view. As a result, for example, in a case where the first electrode and the second electrode are the anode electrode and the cathode electrode of the semiconductor element, the parasitic inductance between the first substrate and the second substrate can be reduced.

In addition, in the first aspect, the second electrode may have a rectangular shape in plan view. Thus, for example, by making the long side of the rectangle parallel to the first direction, the current in the second electrode can flow parallel to the first direction.

Furthermore, in the first aspect, the transistor and the capacitor may be connected in series by the wiring. As a result, for example, the transistor and the capacitor can be connected in series to the semiconductor element.

Furthermore, in the first aspect, the transistor may function as a switch that drives the semiconductor element. As a result, for example, the operation of the semiconductor element can be controlled by this transistor.

Furthermore, in the first aspect, the capacitor may be provided in the second direction of the wiring in plan view. As a result, for example, the current path in the second electrode and the current path in the wiring can be brought close to each other.

Furthermore, in the first aspect, the second substrate may further include a first pad electrically connected to the first connection portion and the transistor, and a second pad electrically connected to the second connection portion and the capacitor. Thus, for example, the first substrate and the second substrate can be electrically connected by disposing the first and second connection portions on the first and second pads.

Furthermore, in the first aspect, the first substrate may further include a first semiconductor substrate containing gallium and arsenic, and the second substrate may further include a second semiconductor substrate containing silicon. As a result, for example, it is possible to provide a transistor or a capacitor on an inexpensive second semiconductor substrate while providing a semiconductor element on a high-performance first semiconductor substrate.

In addition, in the first aspect, the current in the second electrode may flow in parallel to the first direction in plan view. As a result, for example, by making the current path in the second electrode and the current path in the wiring parallel to each other, the current path in the second electrode and the current path in the wiring can be brought close to each other.

In addition, in the first aspect, the current in the second electrode may flow on a straight line connecting the first connection portion and the second connection portion in plan view. As a result, for example, the current in the second electrode can flow in parallel to the first direction in plan view.

Furthermore, in the first aspect, the current in the wiring may flow in parallel to the second direction in plan view. As a result, for example, by making the current path in the second electrode and the current path in the wiring parallel to each other, the current path in the second electrode and the current path in the wiring can be brought close to each other.

Furthermore, in the first aspect, the current in the wiring may flow along a side surface of the wiring in plan view. As a result, for example, the current in the wiring can flow in parallel to the second direction in plan view.

In addition, in the first aspect, an angle between the first direction and the second direction may be 5 degrees or less. As a result, for example, the first direction and the second direction can be made parallel to each other.

Furthermore, in the first aspect, the capacitor may be provided at a position lower than the first and second connection portions. As a result, for example, the capacitor can be manufactured by a semiconductor manufacturing process.

Furthermore, in the first aspect, the second substrate may further include a semiconductor substrate, an insulating film provided on the semiconductor substrate, and third and fourth electrodes provided in the insulating film, and the capacitor may include the third and fourth electrodes. As a result, for example, the capacitor can be manufactured by a semiconductor manufacturing process.

Furthermore, in the first aspect, the second substrate may further include a semiconductor substrate, and the capacitor may be a mounted component provided on the semiconductor substrate. As a result, for example, the capacitor can be easily prepared.

In addition, in the first aspect, a distance between a straight line connecting the first connection portion and the second connection portion and a side surface of the wiring may be equal to or less than a width of the second electrode in plan view. As a result, for example, by reducing this distance, the current path in the second electrode and the current path in the wiring can be brought close to each other.

Furthermore, in the first aspect, a distance between a straight line connecting the first connection portion and the second connection portion and a side surface of the wiring may be equal to or less than a pitch between the plurality of semiconductor elements in a third direction perpendicular to the first direction in plan view. As a result, for example, by reducing this distance, the current path in the second electrode and the current path in the wiring can be brought close to each other.

A distance measuring device according to a second aspect of the present disclosure includes: a light emitting unit that includes a light emitting element that generates light and irradiates a subject with the light from the light emitting element; a light receiving unit that receives light reflected from the subject; and a distance measuring unit that measures a distance to the subject on the basis of the light received by the light receiving unit, in which the light emitting unit includes: a first substrate including a semiconductor element, a first electrode provided on the semiconductor element, and a second electrode extending in a first direction in plan view; a second substrate including a wiring extending in a second direction parallel to the first direction in plan view, a transistor electrically connected to the wiring, and a capacitor electrically connected to the wiring; a first connection portion electrically connecting the first electrode and the second substrate; and a second connection portion electrically connecting the second electrode and the second substrate. As a result, for example, by bringing the current path in the second electrode and the current path in the wiring close to each other, the parasitic inductance between the first substrate and the second substrate can be reduced.

### BRIEF DESCRIPTION OF DRAWINGS

FIG. 1 is a block diagram illustrating a configuration example of a distance measuring device 1 according to a first embodiment.

FIG. 2 is a diagram for explaining a structured light (STL) method of the first embodiment.

FIG. 3 is a cross-sectional view illustrating an example of a structure of a light emitting device 1a of the first embodiment.

FIG. 4 is a cross-sectional view illustrating a structure of the light emitting device 1a illustrated in B of FIG. 3.

FIG. 5 is a plan view and a cross-sectional view illustrating a structure of the light emitting device 1a of the first embodiment.

FIG. 6 is a cross-sectional view and a plan view illustrating a structure of a light emitting device 1a of a comparative example.

FIG. 7 is a circuit diagram and a graph for explaining a problem of the light emitting device 1a of the first embodiment.

FIG. 8 is a circuit diagram for explaining details of the operation of the light emitting device 1a of the first embodiment.

FIG. 9 is a plan view and a cross-sectional view for explaining details of a structure of the light emitting device 1a of the first embodiment.

FIG. 10 is a plan view for explaining details of a structure of the light emitting device 1a of the first embodiment.

FIG. 11 is a plan view and a cross-sectional view illustrating a structure of a light emitting device 1a according to a modification of the first embodiment.

FIG. 12 is a plan view for explaining details of a structure of a light emitting device 1a according to a modification of the first embodiment.

FIG. 13 is a cross-sectional view illustrating a structure of a light emitting device 1a of a second embodiment.

FIG. 14 is a plan view illustrating a structure of a light emitting device 1a of a third embodiment.

### MODE FOR CARRYING OUT THE INVENTION

Hereinafter, embodiments of the present disclosure will be described with reference to the drawings.

### First Embodiment

### (1) Distance Measuring Device 1 of First Embodiment

### (1.1) Configuration of Distance Measuring Device 1

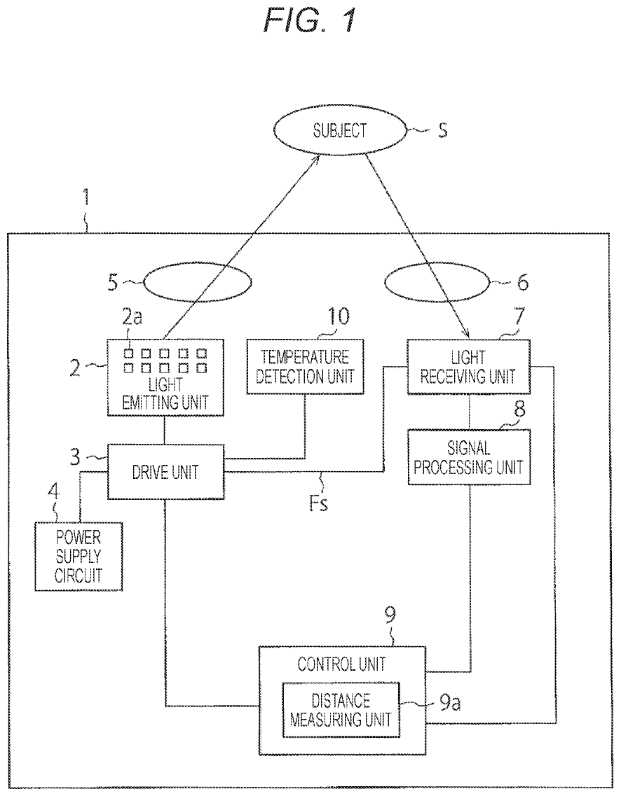

FIG. 1 is a block diagram illustrating a configuration example of a distance measuring device 1 of a first embodiment.

As illustrated in the drawing, the distance measuring device 1 includes a light emitting unit 2, a drive unit 3, a power supply circuit 4, a light-emitting side optical system 5, a light-receiving side optical system 6, a light receiving unit 7, a signal processing unit 8, a control unit 9, and a temperature detection unit 10.

The light emitting unit 2 emits light by a plurality of light sources. The light emitting unit 2 of this example has a light emitting element 2a by a vertical cavity surface emitting laser (VCSEL) as each light source, and these light emitting elements 2a are arranged in a predetermined mode such as a matrix. The drive unit 3 includes a power supply circuit for driving the light emitting unit 2.

The power supply circuit 4 generates a power supply voltage of the drive unit 3 on the basis of, for example, an input voltage from a battery or the like (not illustrated) provided in the distance measuring device 1. The drive unit 3 drives the light emitting unit 2 on the basis of the power supply voltage.

A subject S as a distance measurement target is irradiated with the light emitted from the light emitting unit 2 via the light-emitting side optical system 5. Then, the reflected light from the subject S of the light irradiated in this manner is incident on the light receiving surface of the light receiving unit 7 via the light-receiving side optical system 6.

The light receiving unit 7 is, for example, a light receiving element such as a charge coupled device (CCD) sensor or a complementary metal oxide semiconductor (CMOS) sensor, receives reflected light from the subject S incident through the light-receiving side optical system 6 as described above, converts the reflected light into an electrical signal, and outputs the electrical signal.

The light receiving unit 7 executes, for example, correlated double sampling (CDS) processing, automatic gain control (AGC) processing, and the like on an electrical signal obtained by photoelectrically converting received light, and further performs analog/digital (A/D) conversion processing. Then, the signal as digital data is output to the signal processing unit 8 in the subsequent stage.

Furthermore, the light receiving unit 7 of this example outputs a frame synchronization signal Fs to the drive unit 3. Thus, the drive unit 3 can cause the light emitting elements 2a in the light emitting unit 2 to emit light at timing corresponding to the frame period of the light receiving unit 7.

The signal processing unit 8 is configured as a signal processing processor by, for example, a digital signal processor (DSP) or the like. The signal processing unit 8 performs various types of signal processing on the digital signal input from the light receiving unit 7.

The control unit 9 includes, for example, a microcomputer including a central processing unit (CPU), a read only memory (ROM), a random access memory (RAM), and the like, or an information processing apparatus such as a DSP, and performs control of the drive unit 3 for controlling light emission operation by the light emitting unit 2 and control related to light reception operation by the light receiving unit 7.

The control unit 9 has a function as a distance measuring unit 9a. The distance measuring unit 9a measures the distance to the subject S on the basis of a signal input via the signal processing unit 8 (that is, a signal obtained by receiving reflected light from the subject S). The distance measuring unit 9a of this example measures the distance for each unit of the subject S in order to enable identification of the three-dimensional shape of the subject S.

Here, a specific method for distance measurement in the distance measuring device 1 will be described again later.

The temperature detection unit 10 detects the temperature of the light emitting unit 2. As the temperature detection unit 10, for example, a configuration in which temperature detection is performed using a diode can be adopted.

In this example, the information on the temperature detected by the temperature detection unit 10 is supplied to the drive unit 3, whereby the drive unit 3 can drive the light emitting unit 2 on the basis of the information on the temperature.

### (1.2) Distance Measuring Method

As a distance measuring method in the distance measuring device 1, for example, a distance measuring method by a structured light (STL) method or a time of flight (ToF) method can be adopted.

The STL method is a method for measuring a distance on the basis of an image of the subject S irradiated with light having a predetermined light/dark pattern such as a dot pattern or a lattice pattern.

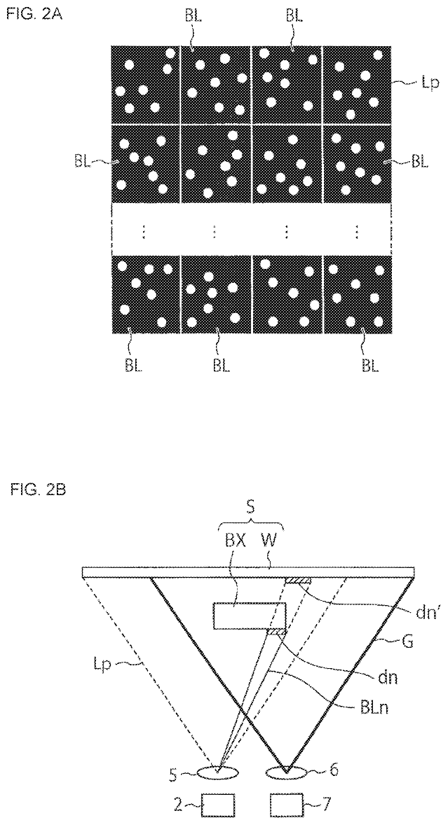

FIG. 2 is a diagram for explaining the STL method of the first embodiment.

In the STL method, for example, the subject S is irradiated with pattern light Lp by a dot pattern as illustrated in A of FIG. 2. The pattern light Lp is divided into a plurality of blocks BL, and different dot patterns are allocated to the respective blocks BL (the dot patterns do not repeat between the blocks B).

B of FIG. 2 is an explanatory diagram of the distance measurement principle of the STL method.

Here, an example in which a wall W and a box BX arranged in front of the wall W are the subject S, and the subject S is irradiated with the pattern light Lp is used. “G” in the drawing schematically represents the angle of view by the light receiving unit 7.

In addition, “BLn” in the drawing means light of a certain block BL in the pattern light Lp, and “dn” means a dot pattern of the block BLn projected on the light receiving image by the light receiving unit 7.

Here, in a case where the box BX in front of the wall W does not exist, the dot pattern of the block BLn is projected at the position of “dn′” in the drawing in the light receiving image. That is, the position at which the pattern of the block BLn is projected in the light receiving image is different between the case where the box BX exists and the case where the box BX does not exist, and specifically, the pattern distortion occurs.

The STL method is a method for obtaining the shape and depth of the subject S by using the fact that the pattern irradiated in this manner is distorted by the object shape of the subject S. Specifically, the STL method is a method for obtaining the shape and depth of the subject S from the way of the distortion of the pattern.

In the case of adopting the STL method, for example, an infrared (IR) light receiving unit by a global shutter method is used as the light receiving unit 7. Then, in the case of the STL method, the distance measuring unit 9a controls the drive unit 3 so that the light emitting unit 2 emits pattern light, detects the distortion of the pattern for the image signal obtained via the signal processing unit 8, and calculates the distance on the basis of the distortion of the pattern.

Subsequently, the ToF method is a method for measuring a distance to a target object by detecting a flight time (time difference) of light emitted from the light emitting unit 2 until the light is reflected by the target object and reaches the light receiving unit 7.

In a case where a so-called direct ToF (dTOF) method is adopted as the ToF method, a single photon avalanche diode (SPAD) is used as the light receiving unit 7, and the light emitting unit 2 is pulse-driven. In this case, the distance measuring unit 9a calculates a time difference between light emission and light reception for light emitted from the light emitting unit 2 and received by the light receiving unit 7 on the basis of a signal input via the signal processing unit 8, and calculates a distance to each unit of the subject S on the basis of the time difference and the speed of light.

Note that, in a case where a so-called indirect ToF (iTOF) method (phase difference method) is adopted as the ToF method, for example, a light receiving unit capable of receiving IR is used as the light receiving unit 7.

### (2) Light Emitting Device 1a of First Embodiment

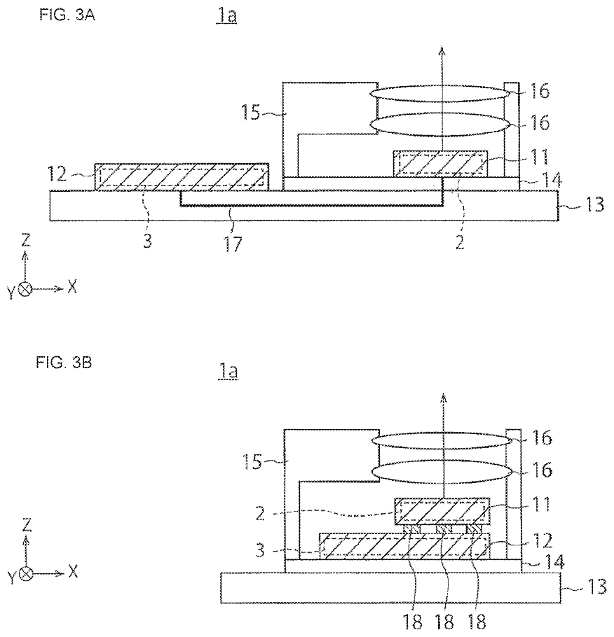

FIG. 3 is a cross-sectional view illustrating an example of a structure of a light emitting device 1a of the first embodiment. The light emitting device 1a of the present embodiment may be a part of the distance measuring device 1 or may be the distance measuring device 1 itself. The light emitting device 1a is an example of the semiconductor device according to the present disclosure.

A of FIG. 3 illustrates a first example of the structure of the light emitting device 1a of the present embodiment. The light emitting device 1a of this example includes a laser diode (LD) chip 11 including the above-described light emitting unit 2, a laser diode driver (LDD) substrate 12 including the above-described drive unit 3, a mounting substrate 13, a heat dissipation substrate 14, a correction lens holding unit 15, one or more correction lenses 16, and wiring 17. The LD chip 11 is also referred to as a VCSEL substrate. The LD chip 11 is an example of a first substrate of the present disclosure, and the LDD substrate 12 is an example of a second substrate of the present disclosure.

A of FIG. 3 illustrates an X axis, a Y axis, and a Z axis perpendicular to each other. An X direction and a Y direction correspond to a lateral direction (horizontal direction), and a Z direction corresponds to a longitudinal direction (vertical direction). In addition, a +Z direction corresponds to an upward direction, and a −Z direction corresponds to a downward direction. The −Z direction may strictly match the gravity direction, or does not necessarily strictly match the gravity direction.

The LD chip 11 is arranged on the mounting substrate 13 with the heat dissipation substrate 14 interposed therebetween, and the LDD substrate 12 is also arranged on the mounting substrate 13. The mounting substrate 13 is, for example, a printed board. On the mounting substrate 13, the light receiving unit 7 and the signal processing unit 8 described above may further be arranged. The heat dissipation substrate 14 is, for example, a ceramic substrate such as an Al₂O₃ (aluminum oxide) substrate or an AlN (aluminum nitride substrate).

The correction lens holding unit 15 is arranged on the heat dissipation substrate 14 so as to surround the LD chip 11, and holds one or more of correction lenses 16 above the LD chip 11. These correction lenses 16 are included in the above-described light-emitting side optical system 5. The light emitted from the light emitting unit 2 in the LD chip 11 is corrected by these correction lenses 16 and then radiated to the subject S described above. A of FIG. 3 illustrates two correction lenses 16 held by the correction lens holding unit 15 as an example.

The wiring 17 is provided on the front surface, the back surface, the inside, or the like of the mounting substrate 13, and electrically connects the LD chip 11 and the LDD substrate 12. The wiring 17 is, for example, printed wiring provided on the front surface or the back surface of the mounting substrate 13 or via wiring penetrating the mounting substrate 13. The wiring 17 of the present embodiment further passes through the inside or the vicinity of the heat dissipation substrate 14.

B of FIG. 3 illustrates a second example of the structure of the light emitting device 1a of the present embodiment. The light emitting device 1a of the present example includes the same components as those of the light emitting device 1a of the first example, but includes bumps 18 instead of the wiring 17.

In B of FIG. 3, the LDD substrate 12 is arranged on the heat dissipation substrate 14, and the LD chip 11 is arranged on the LDD substrate 12. By arranging the LD chip 11 on the LDD substrate 12 in this manner, the size of the mounting substrate 13 can be reduced as compared with the case of the first example. In B of FIG. 3, the LD chip 11 is arranged on the LDD substrate 12 with the bumps 18 interposed therebetween, and is electrically connected to the LDD substrate 12 by the bumps 18. The bumps 18 are formed by metal such as gold (Au), for example.

Hereinafter, the light emitting device 1a of the present embodiment will be described as having the structure of the second example illustrated in B of FIG. 3. However, the following description is also applicable to the light emitting device 1a having the structure of the first example except for the description of the structure specific to the second example.

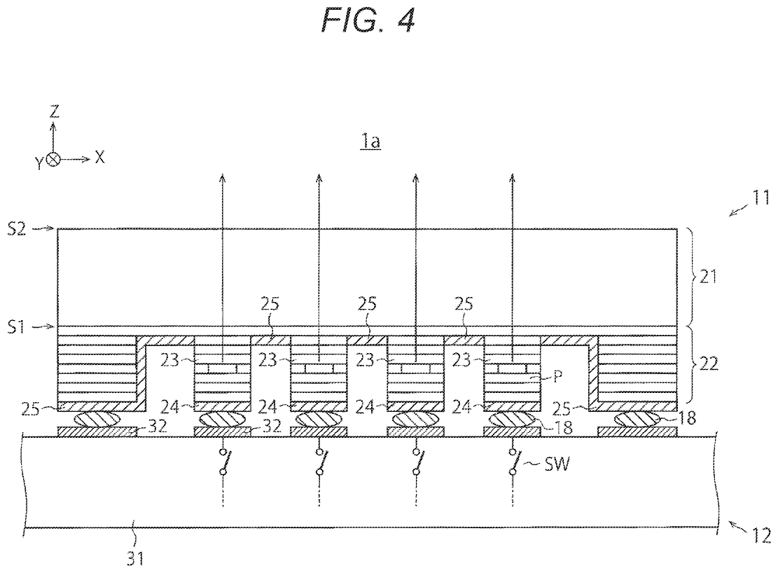

FIG. 4 is a cross-sectional view illustrating a structure of the light emitting device 1a illustrated in B of FIG. 3.

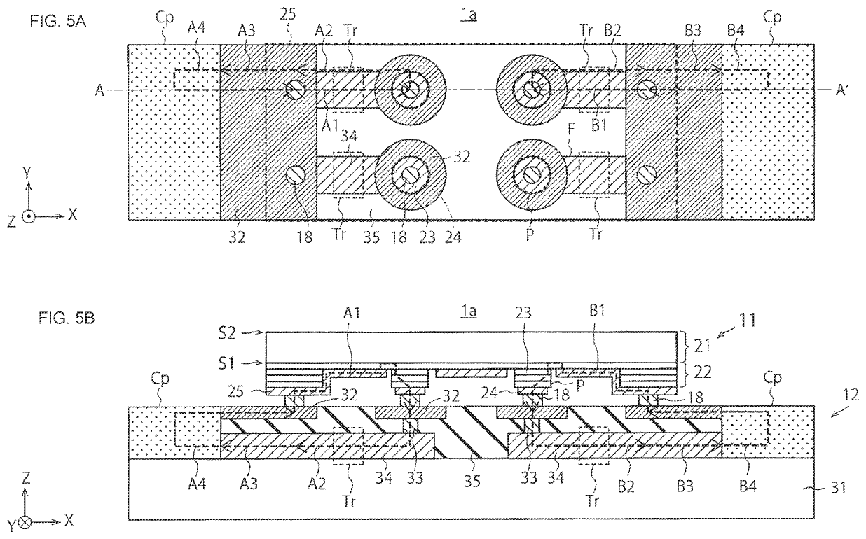

FIG. 4 illustrates cross sections of the LD chip 11 and the LDD substrate 12 in the light emitting device 1a. As illustrated in FIG. 4, the LD chip 11 includes a substrate 21, a laminated film 22, a plurality of light emitting elements 23, a plurality of anode electrodes 24, and cathode electrodes 25, and the LDD substrate 12 includes a substrate 31 and a plurality of connection pads 32. The light emitting element 23 illustrated in FIG. 4 is a specific example of the light emitting element 2a described above. Note that, in FIG. 4, illustration of a plug 33, a wiring 34, an interlayer insulating film 35, and the like, which will be described later, is omitted (see FIG. 5).

The substrate 21 is, for example, a compound semiconductor substrate such as a GaAs (gallium arsenide) substrate. FIG. 4 illustrates a front surface S1 of the substrate 21 facing the −Z direction and a back surface S2 of the substrate 21 facing the +Z direction. The front surface S1 and the back surface S2 illustrated in FIG. 4 are perpendicular to the Z direction. In FIG. 4, the front surface S1 is a lower surface of the substrate 21, and the back surface S2 is an upper surface of the substrate 21. The substrate 21 is an example of a first semiconductor substrate of the present disclosure.

The laminated film 22 includes a plurality of layers laminated on the front surface S1 of the substrate 21. Examples of these layers include an n-type semiconductor layer, an active layer, a p-type semiconductor layer, a light reflecting layer, and an insulating layer having a light emission window. The laminated film 22 includes a plurality of post portions P protruding in the −Z direction. Parts of these post portions P are the plurality of light emitting elements 23.

The light emitting elements 23 are provided on the front surface S1 of the substrate 21 as parts of the laminated film 22. The light emitting elements 23 of the present embodiment have a VCSEL structure and emit light in the +Z direction. As illustrated in FIG. 4, the light emitted from the light emitting elements 23 passes through the substrate 21 from the front surface S1 to the back surface S2 of the substrate 21, and enters the above-described correction lenses 16 from the substrate 21. Thus, the LD chip 11 of the present embodiment is a back-side emission type VCSEL chip. The light emitting element 23 is also called a mesa portion. The light emitting elements 23 are an example of semiconductor elements according to the present disclosure.

Each anode electrode 24 is formed on the lower surface of the corresponding light emitting element 23. The cathode electrode 25 is continuously formed on the lower surface and the side surface of the post portion P other than the light emitting element 23 and the lower surface of the laminated film 22 between the post portions P. Therefore, the LD chip 11 of the present embodiment includes a plurality of anode electrodes 24 and one cathode electrode 25. Each light emitting element 23 emits light when a current flows between the corresponding anode electrode 24 and cathode electrode 25. The anode electrode 24 is an example of a first electrode of the present disclosure, and the cathode electrode 25 is an example of a second electrode of the present disclosure.

As described above, the LD chip 11 is arranged on the LDD substrate 12 with the bumps 18 interposed therebetween, and is electrically connected to the LDD substrate 12 by the bumps 18. Specifically, the connection pads 32 are formed on the substrate 31 included in the LDD substrate 12, and the post portions P are arranged on the connection pads 32 with the bumps 18 interposed therebetween. Each post portion P is arranged on the bump 18 via the anode electrode 24 or the cathode electrode 25. The bump 18 under the anode electrode 24 is an example of a first connection portion of the present disclosure, and the bump 18 under the cathode electrode 25 is an example of a second connection portion of the present disclosure.

The substrate 31 is, for example, a semiconductor substrate such as a silicon (Si) substrate. The substrate 31 is an example of a second semiconductor substrate of the present disclosure. The connection pads 32 are formed on the substrate 31. The connection pad 32 is formed by metal such as copper (Cu), for example. The connection pad 32 under the anode electrode 24 is an example of a first pad of the present disclosure, and the connection pad 32 under the cathode electrode 25 is an example of a second pad of the present disclosure.

As described above, the LDD substrate 12 includes the drive unit 3 that drives the light emitting unit 2 in the LD chip 11. FIG. 4 schematically illustrates a plurality of switches SW in the drive unit 3. Each switch SW is electrically connected to the corresponding light emitting element 23 via the bump 18. The drive unit 3 of the present embodiment can control (turn on and off) these switches SW for each switch SW. Therefore, the drive unit 3 can drive the plurality of light emitting elements 23 for every light emitting element 23. As a result, it is possible to precisely control the light emitted from the light emitting unit 2, for example, by causing only the light emitting elements 23 necessary for distance measurement to emit light or the like. Such individual control of the light emitting elements 23 can be implemented by arranging the LDD substrate 12 below the LD chip 11, so that each light emitting element 23 is easily electrically connected to the corresponding switch SW.

FIG. 5 is a plan view and a cross-sectional view illustrating a structure of the light emitting device 1a of the first embodiment.

A of FIG. 5 illustrates a planar structure of the light emitting device 1a of the present embodiment. Similarly to FIG. 4, B of FIG. 5 illustrates a longitudinal cross section of the light emitting device 1a of the present embodiment. B of FIG. 5 illustrates a longitudinal cross section taken along line A-A′ illustrated in A of FIG. 5. Hereinafter, the structure of the light emitting device 1a of the present embodiment will be described with reference to A and B of FIG. 5.

As illustrated in A and B of FIG. 5, the LD chip 11 includes a substrate 21, a laminated film 22, a plurality of light emitting elements 23, a plurality of anode electrodes 24, and a cathode electrode 25. A of FIG. 5 illustrates a planar shape of the four light emitting elements 23 in the LD chip 11, and B of FIG. 5 illustrates a longitudinal cross section of two of the light emitting elements 23. In A of FIG. 5, the shape of the anode electrode 24 is indicated by a dotted line, and the shape of the cathode electrode 25 is indicated by a broken line. A and B of FIG. 5 further illustrate two post portions P other than the light emitting element 23.

As illustrated in A and B of FIG. 5, the LDD substrate 12 includes a substrate 31, a plurality of connection pads 32, a plurality of plugs 33, a plurality of wirings 34, an interlayer insulating film 35, a plurality of transistors Tr, and a plurality of capacitors Cp. In A and B of FIG. 5, a rough range in which the transistor Tr is provided is indicated by a broken line.

Details of these components of the LD chip 11 and the LDD substrate 12 will be described below.

### [Anode Electrode 24 and Cathode Electrode 25]

As illustrated in A of FIG. 5, each anode electrode 24 of the present embodiment has a circular shape in plan view. On the other hand, the cathode electrode 25 of the present embodiment has a rectangular shape in plan view as illustrated in A of FIG. 5. The two long sides of the rectangle are parallel to the X direction, and the two short sides of the rectangle are parallel to the Y direction. Therefore, the cathode electrode 25 extends in the X direction in plan view. The X direction is an example of the first direction of the present disclosure.

However, the cathode electrode 25 of the present embodiment has an opening portion at the position of each anode electrode 24 in plan view. Therefore, the planar shape of the cathode electrode 25 illustrated in A of FIG. 5 is a rectangle having four circular opening portions. As a result, the cathode electrode 25 has a shape surrounding each anode electrode 24 in plan view. The plurality of anode electrodes 24 and cathode electrodes 25 described above of the present embodiment are separated from each other.

Note that the planar shape of each anode electrode 24 may be other than a circular shape. In addition, the planar shape of the cathode electrode 25 may be other than a rectangular shape.

### [Light Emitting Element 23]

Regarding the four light emitting elements 23 illustrated in A of FIG. 5, the upper left light emitting element 23 and the lower left light emitting element 23 are electrically connected to the left capacitor Cp. On the other hand, the upper right light emitting element 23 and the lower right light emitting element 23 are electrically connected to the right capacitor Cp.

Furthermore, the upper left light emitting element 23 is electrically connected to the left capacitor Cp via the upper left transistor Tr. Similarly, the lower left light emitting element 23 is electrically connected to the left capacitor Cp via the lower left transistor Tr. On the other hand, the upper right light emitting element 23 is electrically connected to the right capacitor Cp via the upper right transistor Tr. Similarly, the lower right light emitting element 23 is electrically connected to the right capacitor Cp via the lower right transistor Tr.

In this manner, each light emitting element 23 is electrically connected to the corresponding capacitor Cp via the corresponding transistor Tr. Each transistor Tr of the present embodiment functions as the above-described switch SW (FIG. 4). Therefore, each transistor Tr can drive the corresponding light emitting element 23.

A and B of FIG. 5 illustrate current paths A1 to A4 of the current flowing through the light emitting element 23 on the upper left and current paths B1 to B4 of the current flowing through the light emitting element 23 on the upper right. The current path A1 illustrates a path from the connection pad 32 under the cathode electrode 25 to the connection pad 32 under the anode electrode 24. The current path A2 indicates a path in the connection pad 32, the plug 33, the transistor Tr, and the wiring 34. The current path A3 indicates a path in the wiring 34. The current path A4 indicates a path in the capacitor Cp and the connection pad 32.

It similarly applies to the current paths B1 to B4. However, the current paths A1 to A4 illustrated in B of FIG. 5 are clockwise, and the current paths B1 to B4 illustrated in B of FIG. 5 are counterclockwise.

Note that a current path (not illustrated) of the current flowing through the lower left light emitting element 23 is similar to the current paths A1 to A4 of the current flowing through the upper left light emitting element 23. In addition, a current path (not illustrated) of the current flowing through the lower right light emitting element 23 is similar to the current paths B1 to B4 of the current flowing through the upper right light emitting element 23. Further details of the current paths A1 to A4 and the like will be described later.

### [LDD Substrate 12]

As illustrated in A and B of FIG. 5, the LDD substrate 12 includes a plurality of wirings 34, a plurality of plugs 33, and a plurality of connection pads 32 sequentially formed on the substrate 31. The wiring 34, the plug 33, and the connection pad 32 are provided in an interlayer insulating film 35 formed on the substrate 31. The interlayer insulating film 35 is an example of an insulating film of the present disclosure. The LDD substrate 12 further includes a plurality of transistors Tr and a plurality of capacitors Cp formed on the substrate 31 and provided in the interlayer insulating film 35.

A of FIG. 5 illustrates four wirings 34 corresponding to the four light emitting elements 23. These wirings 34 extend in the X direction in plan view. The X direction is an example of the second direction of the present disclosure. Hereinafter, further details of the light emitting element 23 and the wiring 34 will be described using the light emitting element 23 on the upper left and the wiring 34 on the upper left as examples.

B of FIG. 5 illustrates the upper left light emitting element 23 and the upper left wiring 34, and further illustrates the plug 33, the connection pad 32, the bump 18, and the anode electrode 24 sequentially provided on the upper left wiring 34. The bump 18 is an example of a first connection portion of the present disclosure. The light emitting element 23 on the upper left is provided on the anode electrode 24. The upper left wiring 34 is electrically connected to the left capacitor Cp and the lower left transistor Tr, and connects the left capacitor Cp and the lower left transistor Tr in series.

The capacitor Cp is provided in the interlayer insulating film 35 similarly to the wiring 34, the plug 33, and the connection pad 32. Therefore, the capacitor Cp is provided at a position lower than each bump 18 between the LD chip 11 and the LDD substrate 12. In addition, the capacitor Cp is arranged on the left side (−X direction) of the upper left wiring 34 in plan view.

As illustrated in B of FIG. 5, the capacitor Cp is electrically connected to the cathode electrode 25 via the connection pad 32 and the bump 18. As a result, current paths A1 to A4 are formed for the capacitor Cp. The bump 18 is an example of a second connection portion of the present disclosure. A of FIG. 5 illustrates four bumps 18 electrically connected to the cathode electrode 25, and one of the bumps 18 forms the current paths A1 to A4.

### [Current Paths A1 to A4]

A and B of FIG. 5 illustrate current paths A1 to A4 of the current flowing through the light emitting element 23 on the upper left and current paths B1 to B4 of the current flowing through the light emitting element 23 on the upper right. The current path A1 illustrates a path from the connection pad 32 under the cathode electrode 25 to the connection pad 32 under the anode electrode 24. The current path A2 indicates a path in the connection pad 32, the plug 33, the transistor Tr, and the wiring 34. The current path A3 indicates a path in the wiring 34. The current path A4 indicates a path in the capacitor Cp and the connection pad 32. It similarly applies to the current paths B1 to B4.

As illustrated in A of FIG. 5, the current path A1 is located on a straight line connecting the center of the bump 18 under the cathode electrode 25 and the center of the bump 18 under the anode electrode 24 in plan view. Therefore, the current in the current path A1 flows parallel to the X direction in plan view. Note that the straight line described above is located on line A-A′ illustrated in A of FIG. 5.

Most of the current path A2 is located on the side surface F of the wiring 34 in plan view. This is because the current in the wiring 34 generally flows along the side surface F of the wiring 34. The current path A2 is located on the side surface F of the wiring 34 in the +Y direction in A of FIG. 5, but may be located on the side surface F of the wiring 34 in the −Y direction. That is, the current in the current path A2 may flow along the side surface F in the +Y direction of the wiring 34 or may flow along the side surface F in the −Y direction of the wiring 34. In the present embodiment, since the wiring 34 extends in the Y direction, the current in the wiring 34 flows parallel to the Y direction.

The current path A3 is located on the side surface F of the wiring 34 in plan view. The reason is similar to the case of the current path A2. It should be noted that, in A of FIG. 5, the wiring 34 exists below the connection pad 32.

The current path A4 extends from the end point of the current path A3 to the start point of the current path A1 in plan view. For example, the current path A4 in the connection pad 32 is located on the line A-A′ in plan view, similarly to the current path A1.

Therefore, the current paths A1 to A4 illustrated in A of FIG. 5 have an elongated rectangular shape in plan view. This rectangle has a shape in which the long side is significantly longer than the short side. Advantages of the current paths A1 to A4 having such shapes will be described later. Note that the planar shape of the current paths A1 to A4 may be other than a rectangle.

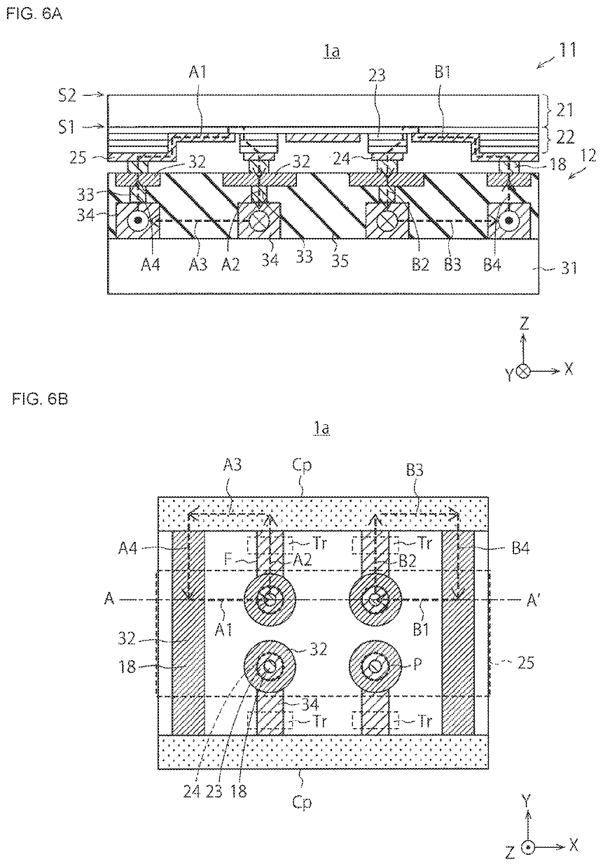

FIG. 6 is a cross-sectional view and a plan view illustrating a structure of a light emitting device 1a of a comparative example.

A of FIG. 6 illustrates a longitudinal cross section of the light emitting device 1a of the present comparative example. B of FIG. 6 illustrates a planar structure of the light emitting device 1a of the present comparative example. A of FIG. 6 illustrates a longitudinal cross section taken along line A-A′ illustrated in B of FIG. 6. Hereinafter, a structure of the light emitting device 1a of the present comparative example will be described with reference to A and B of FIG. 6.

The light emitting device 1a of the present comparative example includes components similar to those of the light emitting device 1a of the first embodiment. However, as illustrated in B of FIG. 6, the capacitor Cp of the present comparative example is arranged in the +Y direction of the light emitting element 23 in plan view. Therefore, the wiring 34 of the present comparative example extends in the Y direction in plan view.

As a result, as illustrated in B of FIG. 6, the current paths A1 to A4 of the present comparative example have planar shapes different from the planar shapes of the current paths A1 to A4 of the first embodiment. Specifically, the current paths A1 to A4 of the first embodiment have an elongated rectangular shape in plan view, but the current paths A1 to A4 of the present comparative example have a rectangular shape that is not elongated in plan view. In addition, most of the current path A2 of the first embodiment is parallel to the current path A1 in plan view, but the current path A2 of the present comparative example is perpendicular to the current path A1 in plan view.

Therefore, the current path A1 of the present comparative example is disposed far from most of the current paths A2 to A4. Therefore, the magnetic field generated by the current in the current path A1 is less likely to cancel out the magnetic field generated by the current in the current paths A2 to A4. As a result, a large parasitic inductance is generated between the LD chip 11 and the LDD substrate 12 of the present comparative example.

On the other hand, the current path A1 of the first embodiment is arranged near most of the current paths A2 to A4. Therefore, the magnetic field generated by the current in the current path A1 easily cancels out the magnetic field generated by the current in the current paths A2 to A4. Therefore, according to the present embodiment, the parasitic inductance between the LD chip 11 and the LDD substrate 12 can be reduced. For example, according to the present embodiment, the parasitic inductance between the LD chip 11 and the LDD substrate 12 can be set to about a fraction of that of the comparative example described above.

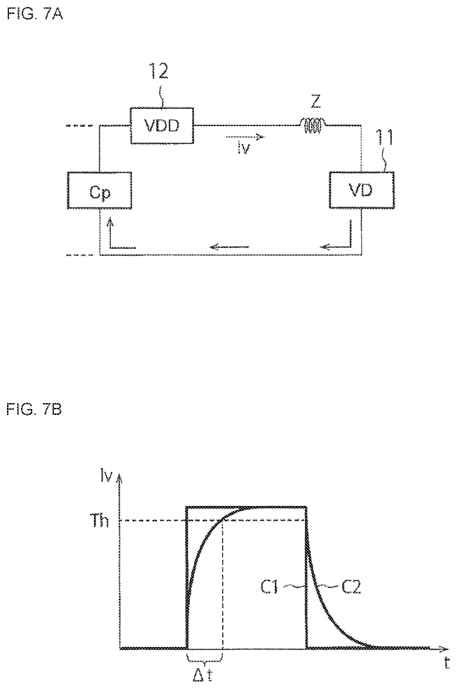

FIG. 7 is a circuit diagram and a graph for explaining a problem of the light emitting device 1a of the first embodiment.

A of FIG. 7 illustrates an equivalent circuit of the light emitting device 1a of the present embodiment. The equivalent circuit illustrated in A of FIG. 7 includes an LD chip 11 forming the circuit, an LDD substrate 12 (excluding the capacitor Cp), a capacitor Cp in the LDD substrate 12, and a parasitic inductance Z between the LD chip 11 and the LDD substrate 12. A of FIG. 7 further illustrates a current Iv (VCSEL current) flowing in the circuit.

B of FIG. 7 illustrates a temporal change of the current Iv. A curve C1 indicates the current Iv in a case where the parasitic inductance Z is small, and a curve C2 indicates the current Iv in a case where the parasitic inductance Z is large. Reference signs Δt and Th respectively represent a rising delay and a rising threshold of the current Iv.

As illustrated in B of FIG. 7, when the parasitic inductance Z is large, the rising of the current Iv is delayed, and an error occurs in the detection of the rising time. As a result, an error occurs in the distance measurement by the distance measuring device 1 (FIG. 1). According to the present embodiment, such an error can be suppressed by reducing the parasitic inductance Z.

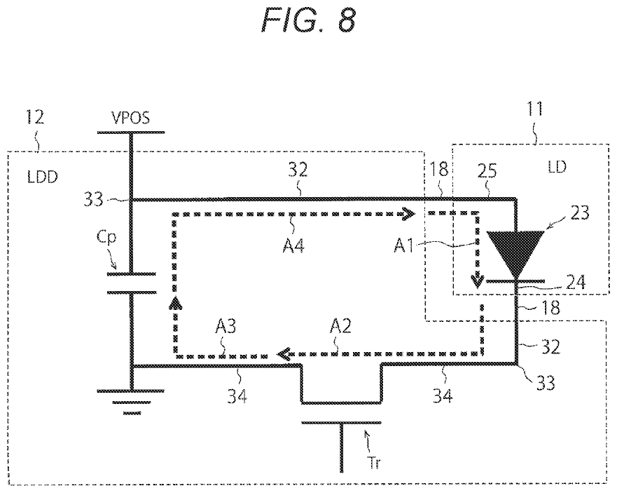

FIG. 8 is a circuit diagram for explaining details of the operation of the light emitting device 1a of the first embodiment.

FIG. 8 illustrates an equivalent circuit of the light emitting device 1a of the present embodiment. The equivalent circuit illustrated in FIG. 8 includes a light emitting element 23 in the LD chip 11, a transistor Tr in the LDD substrate 12, a capacitor Cp in the LDD substrate 12, and the like. FIG. 8 further illustrates current paths A1 to A4 between these components.

As described above, in the present embodiment, the magnetic field generated by the current in the current path A1 easily cancels out the magnetic field generated by the current in the current paths A2 to A4. Therefore, according to the present embodiment, the parasitic inductance between the LD chip 11 and the LDD substrate 12 can be reduced.

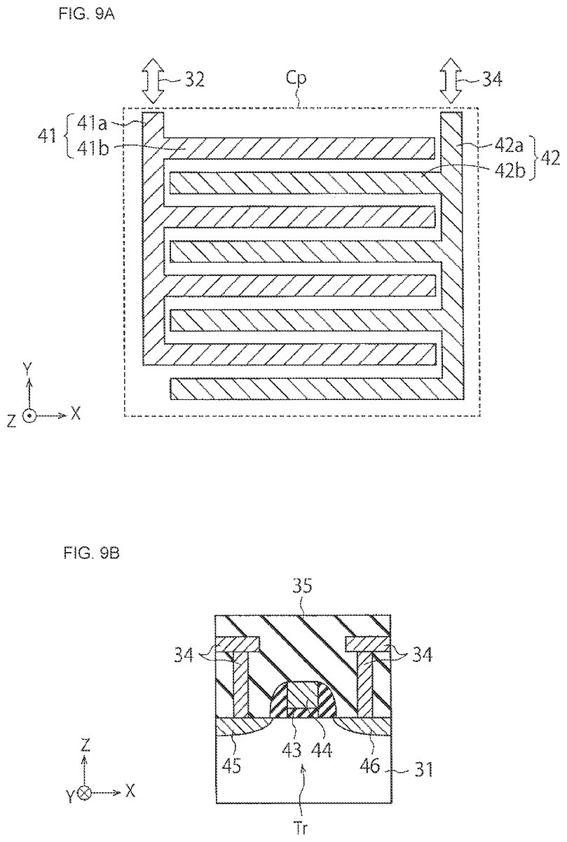

FIG. 9 is a plan view and a cross-sectional view for explaining details of the structure of the light emitting device 1a of the first embodiment.

A of FIG. 9 illustrates a configuration example of the capacitor Cp. As described above, the capacitor Cp is provided in the interlayer insulating film 35 on the substrate 31 (B of FIG. 5). In A of FIG. 9, the capacitor Cp includes an electrode 41 and an electrode 42. These electrodes 41 and 42 are formed in the interlayer insulating film 35. The capacitor Cp illustrated in A of FIG. 9 includes these electrodes 41 and 42 and an interlayer insulating film 35 between these electrodes 41 and 42.

The electrode 41 includes a common portion 41a electrically connected to the connection pad 32 and a plurality of tip portions 41b extending from the common portion 41a. Similarly, the electrode 42 includes a common portion 42a electrically connected to the wiring 34 and a plurality of tip portions 42b extending from the common portion 42a. The electrodes 41 and 42 constitute a comb-shaped electrode in which a plurality of tip portions 41b and a plurality of tip portions 42b are alternately arranged in plan view. This makes it possible to increase the capacitance of the capacitor Cp. The electrodes 41 and 42 are examples of the third and fourth electrodes of the present disclosure.

According to the present embodiment, by adopting the capacitor Cp having such a structure, the capacitor Cp can be manufactured by a semiconductor manufacturing process similarly to the connection pad 32, the plug 33, the wiring 34, the interlayer insulating film 35, and the like. Note that the capacitor Cp may have a structure other than the structure illustrated in A of FIG. 9.

B of FIG. 9 illustrates a configuration example of the transistor Tr. As described above, the transistor Tr is provided in the interlayer insulating film 35 on the substrate 31 (B of FIG. 5). In B of FIG. 9, the transistor Tr includes a gate insulating film 43, a gate electrode 44, one diffusion layer 45, and the other diffusion layer 46, and forms a MOS transistor.

The gate insulating film 43 is formed on the substrate 31. The gate electrode 44 is formed on the gate insulating film 43. The diffusion layers 45 and 46 are formed in the substrate 31 so as to sandwich the gate electrode 44, and function as source and drain regions of the transistor Tr.

The gate insulating film 43 and the gate electrode 44 are provided in the interlayer insulating film 35 on the substrate 31. In B of FIG. 9, a part of the wiring 34 is electrically connected to the diffusion layer 45, and another part of the wiring 34 is electrically connected to the diffusion layer 46. As a result, the transistor Tr is disposed on the wiring 34.

The wiring 34 illustrated in B of FIG. 9 includes a contact plug provided on the diffusion layer 45, a contact plug provided on the diffusion layer 46, and two wirings in the wiring layer provided on these contact plugs. One wiring in the wiring layer is electrically connected to the diffusion layer 45 and the capacitor Cp (not illustrated), and the other wiring in the wiring layer is electrically connected to the diffusion layer 46 and the plug 33 (not illustrated).

Note that the transistor Tr and the wiring 34 may have a structure other than the structure illustrated in B of FIG. 9. For example, the wiring 34 may be formed by a plurality of wirings in two or more wiring layers included in the interlayer insulating film 35.

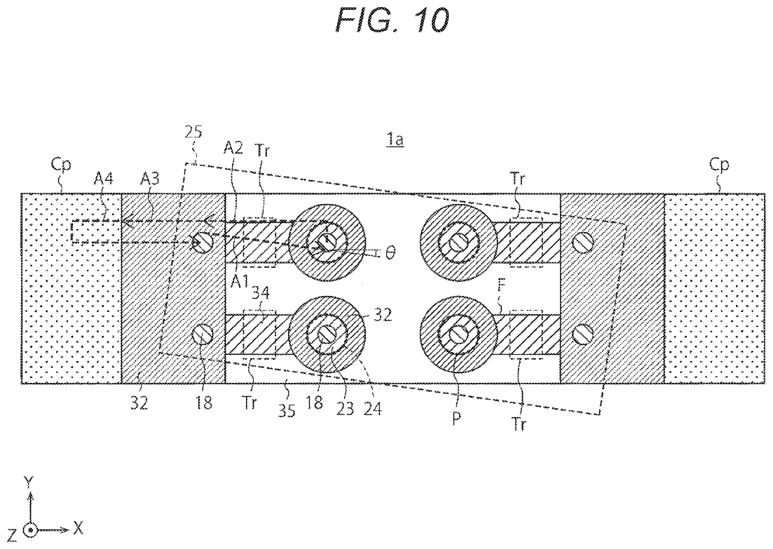

FIG. 10 is a plan view for explaining the details of the structure of the light emitting device 1a of the first embodiment.

As described with reference to A and B of FIG. 5, the direction (first direction) in which the cathode electrode 25 of the present embodiment extends in plan view is the X direction, and the direction (second direction) in which the wiring 34 of the present embodiment extends in plan view is also the X direction. Therefore, the second direction of the present embodiment is parallel to the first direction. However, this “parallel” may not be mathematically exact “parallel”. For example, a case where the second direction is parallel to the first direction includes not only a case where the second direction is mathematically strictly parallel to the first direction, but also a case where the second direction is different from the first direction by a degree of a manufacturing error. This will be described with reference to FIG. 10.

FIG. 10 illustrates an angle θ between the direction (first direction) in which the cathode electrode 25 extends in plan view and the direction (second direction) in which the wiring 34 extends in plan view (0 degrees≤θ<180 degrees). In FIG. 10, the second direction coincides with the X direction, and the first direction is inclined by an angle θ with respect to the X direction.

The angle θ of the present embodiment is 5 degrees or less. In other words, the second direction being parallel to the first direction in the present embodiment corresponds to the angle θ being 5 degrees or less. According to the present embodiment, by arranging the cathode electrode 25, the wiring 34, and the like such that the angle θ is 5 degrees or less, it is possible to reduce the parasitic inductance between the LD chip 11 and the LDD substrate 12. In addition, according to the present embodiment, by allowing an error of 5 degrees or less in the angle θ, it is possible to improve the degree of freedom in designing the light emitting device 1a.

FIG. 10 illustrates current paths A1 to A4 similarly to A and B of FIG. 5. In FIG. 10, since the direction (first direction) in which the cathode electrode 25 extends in plan view is inclined with respect to the X direction, the current path A2 is also inclined with respect to the X direction. Also in this case, it is possible to effectively cancel the magnetic field generated by the current in the current path A1 with the magnetic field generated by the current in the current paths A2 to A4.

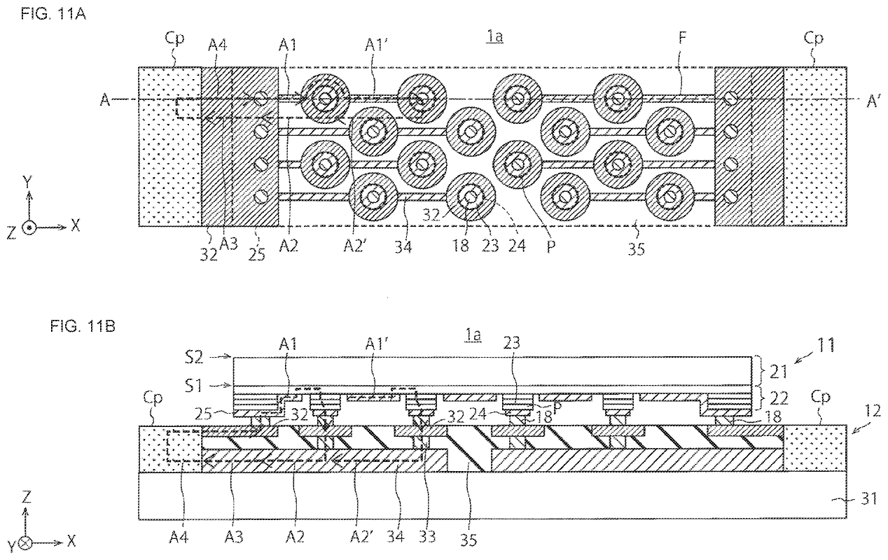

FIG. 11 is a plan view and a cross-sectional view illustrating a structure of a light emitting device 1a according to a modification of the first embodiment.

A of FIG. 11 illustrates a planar structure of a light emitting device 1a of the present modification. B of FIG. 11 illustrates a longitudinal cross section of a light emitting device 1a of the present modification. B of FIG. 11 illustrates a longitudinal cross section taken along line A-A′ illustrated in A of FIG. 11. Hereinafter, a structure of a light emitting device 1a of the present modification will be described with reference to A and B of FIG. 11.

As illustrated in A and B of FIG. 11, a light emitting device 1a of the present modification includes components similar to those of the light emitting device 1a of the first embodiment (see A and B of FIG. 5). However, A of FIG. 11 illustrates a configuration example of a light emitting device 1a including five or more light emitting elements 23. Specifically, A of FIG. 11 illustrates an arrangement example of 16 light emitting elements 23, and B of FIG. 11 illustrates four of these light emitting elements 23.

A and B of FIG. 11 illustrate current paths A1′ and A2′ in addition to current paths A1 to A4. The current paths A1 to A4, A1′, and A2′ include two light emitting elements 23. Hereinafter, the left of these light emitting elements 23 is referred to as “left light emitting element 23”, and the right of these light emitting elements 23 is referred to as “right light emitting element 23”.

The left light emitting element 23 and the right light emitting element 23 are connected in parallel to the left capacitor Cp by current paths A1 to A4, A1′, and A2′. It similarly applies to the other 14 light emitting elements 23 illustrated in A of FIG. 11. The 16 light emitting elements 23 illustrated in A of FIG. 11 constitute eight light emitting element groups, and each light emitting element group includes two light emitting elements 23. The two light emitting elements 23 in each light emitting element group are connected in parallel to the left or right capacitor Cp. For example, the left light emitting element 23 and the right light emitting element 23 described above constitute one of the eight light emitting element groups, and are connected in parallel with the left capacitor Cp.

Hereinafter, the current paths A1 to A4, A1′, and A2′ will be described.

As illustrated in A of FIG. 11, the current path A1 is located on a straight line connecting the bump 18 under the cathode electrode 25 and the bump 18 under the anode electrode 24 of the left light emitting element 23 in plan view. In addition, the current path A1′ is located on a straight line connecting the bump 18 under the anode electrode 24 of the left light emitting element 23 and the bump 18 under the anode electrode 24 of the right light emitting element 23 in plan view. However, a part of the current path A1′ has a semicircular shape in the vicinity of the left light emitting element 23 in order to bypass the left light emitting element 23. Therefore, the currents in the current paths A1 and A1′ flow substantially parallel to the X direction in plan view. Note that the current path A1′ bypasses the left light emitting element 23 in the +Y direction in A of FIG. 11, but may bypass the left light emitting element 23 in the −Y direction instead.

Most of the current paths A2 and A2′ are located on the side surface F of the wiring 34 in plan view. However, A of FIG. 11 illustrates the current paths A2 and A2′ apart from the side surface F of the wiring 34 in order to avoid the current paths A1 and A1′ and the current paths A2 and A2′ being overlapped and illustrated. Actually, the current paths A2 and A2′ are located on the side surface F of the wiring 34 in the −Y direction in plan view. Note that the current paths A2 and A2′ may be located on the side surface F of the wiring 34 in the +Y direction. In the present modification, since the wiring 34 extends in the Y direction, the current in the wiring 34 flows parallel to the Y direction.

Note that, in A of FIG. 11, illustration of a portion near the end point of the current path A1 and a portion near the start point of the current path A2 is omitted in order to avoid difficulty in viewing the drawing. Actually, as illustrated in B of FIG. 11, the vicinity of the end point of the current path A1 extends to the start point of the current path A2.

The current path A3 is located on the side surface F of the wiring 34 in plan view. However, A of FIG. 11 illustrates the current path A3 separated from the side surface F of the wiring 34 in order to avoid the current path A1 and the current path A3 being overlapped and illustrated. Actually, the current path A3 is located on the side surface F of the wiring 34 in the −Y direction in plan view. Note that the current path A3 may be located on the side surface F of the wiring 34 in the +Y direction.

The current path A4 extends from the end point of the current path A3 to the start point of the current path A1 in plan view. For example, the current path A4 in the connection pad 32 is located on the line A-A′ in plan view, similarly to the current paths A1 and A1′.

Therefore, the current paths A1 to A4, A1′, and A2′ illustrated in A of FIG. 11 have two elongated rectangular shapes in plan view. Each of these rectangles has a shape in which a long side is significantly longer than a short side. Therefore, according to the present modification, the parasitic inductance between the LD chip 11 and the LDD substrate 12 can be reduced.

Note that the left light emitting element 23 and the right light emitting element 23 may be controlled by one transistor Tr provided on the wiring 34, or may be controlled by two transistors Tr provided on the wiring 34. That is, the left light emitting element 23 and the right light emitting element 23 may be controlled by the same one transistor Tr or may be controlled by two different transistors Tr. It similarly applies to the other 14 light emitting elements 23 illustrated in A of FIG. 11.

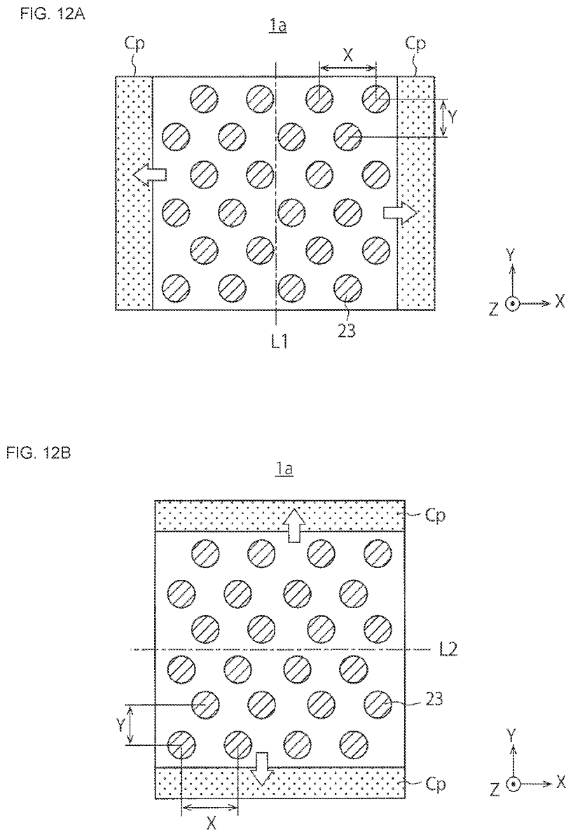

FIG. 12 is a plan view for explaining details of a structure of a light emitting device 1a according to a modification of the first embodiment.

A of FIG. 12 illustrates a layout of the plurality of light emitting elements 23 included in the light emitting device 1a of the present modification, similarly to A of FIG. 11. In A of FIG. 12, these light emitting elements 23 are arranged in a two-dimensional array. Note that these light emitting elements 23 are arranged in a triangular lattice shape in A of FIG. 12, but may be arranged in another layout (for example, a square lattice shape).

A of FIG. 12 illustrates a straight line L1 passing between these light emitting elements 23. In the present modification, each light emitting element 23 located in the +X direction of the straight line L1 is electrically connected to the right capacitor Cp, and each light emitting element 23 located in the −X direction of the straight line L1 is electrically connected to the left capacitor Cp. As a result, the parasitic inductance between the LD chip 11 and the LDD substrate 12 can be reduced.

A of FIG. 12 further illustrates a pitch “X” in the X direction between the light emitting elements 23 and a pitch “Y” in the Y direction between the light emitting elements 23. Since the light emitting elements 23 of the present modification are arranged in a triangular lattice shape, the pitch “X” is the base of one triangle constituting the triangular lattice, and the pitch “Y” is the height of one triangle constituting the triangular lattice.

B of FIG. 12 illustrates a layout of the plurality of light emitting elements 23 included in the light emitting device 1a of the comparative example of the present embodiment. In B of FIG. 12, two capacitors Cp are arranged in the +Y direction of the light emitting element 23.

B of FIG. 12 illustrates a straight line L2 passing between these light emitting elements 23. In the present comparative example, each light emitting element 23 located in the +Y direction of the straight line L2 is electrically connected to the upper capacitor Cp, and each light emitting element 23 located in the −Y direction of the straight line L2 is electrically connected to the lower capacitor Cp. In this case, as described with reference to A and B of FIG. 6, the parasitic inductance between the LD chip 11 and the LDD substrate 12 increases.

As described above, in the light emitting device 1a of the present embodiment, the capacitor Cp and the like are arranged such that the direction (second direction) in which the wiring 34 extends in plan view is parallel to the direction (first direction) in which the cathode electrode 25 extends in plan view. Therefore, according to the present embodiment, the parasitic inductance between the LD chip 11 and the LDD substrate 12 can be reduced by canceling the magnetic fields generated by the current.

### Second Embodiment

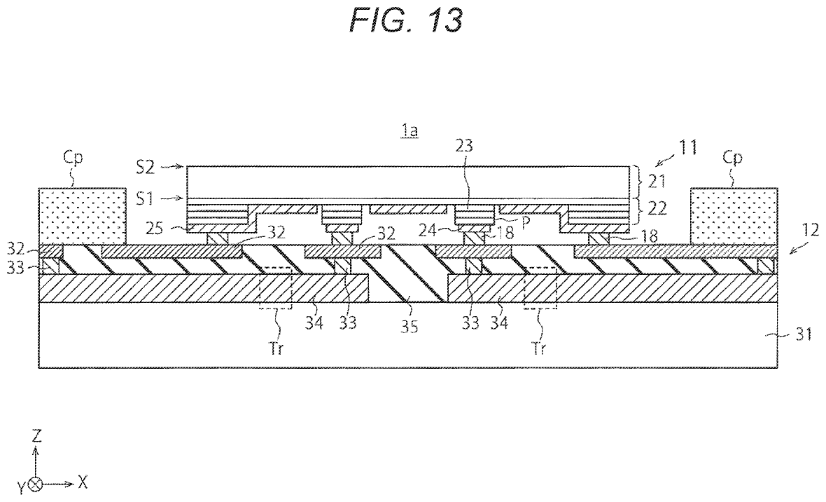

FIG. 13 is a cross-sectional view illustrating a structure of a light emitting device 1a of a second embodiment.

FIG. 13 illustrates a longitudinal cross section of the light emitting device 1a of the present embodiment. The light emitting device 1a of the present embodiment includes components similar to those of the light emitting device 1a of the first embodiment (see B of FIG. 5). However, the capacitor Cp of the present embodiment is a mounted component disposed on the substrate 31. The capacitor Cp of the present embodiment is, for example, a commercially available capacitor.

In FIG. 13, each capacitor Cp is disposed on the interlayer insulating film 35. One electrode (not illustrated) of each capacitor Cp is electrically connected to the cathode electrode 25 via the connection pad 32 and the bump 18. The other electrode (not illustrated) of each capacitor Cp is electrically connected to the anode electrode 24 via the two connection pads 32, the two plugs 33, the wiring 34, and the bump 18.

According to the present modification, for example, the capacitor Cp can be easily prepared by purchasing the capacitor Cp without manufacturing the capacitor Cp by itself. Alternatively, the capacitor Cp may be manufactured without a semiconductor manufacturing process.

### Third Embodiment

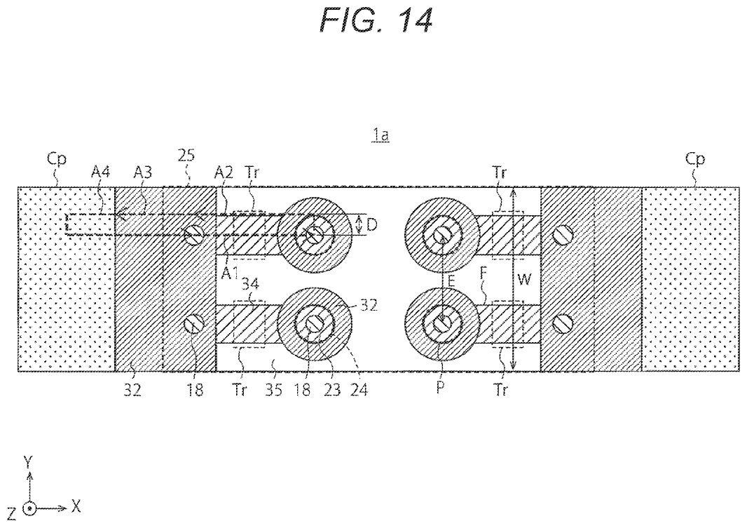

FIG. 14 is a plan view illustrating a structure of a light emitting device 1a of a third embodiment.

FIG. 14 illustrates a planar structure of the light emitting device 1a of the present embodiment. The light emitting device 1a of the present embodiment includes components similar to those of the light emitting device 1a of the first embodiment (see A of FIG. 5). FIG. 14 illustrates a width W in the Y direction of the substrate 21 and the cathode electrode 25 of the present embodiment.

### [Distance D]

FIG. 14 further illustrates a distance D between the current path A1 and the current path A2 in plan view. The current path A1 is located on a straight line connecting the center of the bump 18 under the cathode electrode 25 and the center of the bump 18 under the anode electrode 24 in plan view. The current path A2 is located on the side surface F of the wiring 32 in plan view. Therefore, the distance D corresponds to a distance between the straight line and the side surface F.

In the present embodiment, the distance D is set to be equal to or less than the width W (D≤W). In the present embodiment, since the capacitor Cp is arranged in the #X direction of the light emitting element 23, such a setting can be realized. According to the present embodiment, by setting the distance D to be equal to or less than the width W, the current path A1 and the current path A2 can be brought close to each other, and the parasitic inductance between the LD chip 11 and the LDD substrate 12 can be effectively reduced.

Note that the width of the substrate 21 in the Y direction and the width of the cathode electrode 25 in the Y direction may be different from each other. In this case, the distance D may be equal to or less than both of these widths, or may be equal to or less than only one of these widths.

### [Pitch E]

FIG. 14 further illustrates a pitch E in the Y direction between the light emitting elements 23. The Y direction is an example of a third direction of the present disclosure.

In the present embodiment, the distance D is set to be equal to or less than the pitch E (D≤ E). In the present embodiment, since the capacitor Cp is arranged in the +X direction of the light emitting element 23, such a setting can be realized. According to the present embodiment, by setting the distance D to be equal to or less than the pitch E, the current path A1 and the current path A2 can be further brought closer to each other, and the parasitic inductance between the LD chip 11 and the LDD substrate 12 can be further effectively reduced.

Note that the light emitting element 23 of the present embodiment may be arranged in any two-dimensional layout. For example, in a case where the light emitting elements 23 are arranged in a triangular lattice shape, the pitch E illustrated in FIG. 14 is the pitch “Y” illustrated in A of FIG. 12.

Note that the light emitting device 1a of the first to third embodiments is used as a light source of the distance measuring device 1, but may be used in other modes. For example, the light emitting devices 1a of these embodiments may be used as a light source of an optical apparatus such as a printer, or may be used as a lighting device.

Although the embodiments of the present disclosure have been described above, these embodiments may be implemented with various modifications within a scope not departing from the gist of the present disclosure. For example, two or more embodiments may be implemented in combination.

Note that the present disclosure can also have the following configurations.

(1)

A semiconductor device including:
a first substrate including a semiconductor element, a first electrode provided on the semiconductor element, and a second electrode extending in a first direction in plan view;
a second substrate including a wiring extending in a second direction parallel to the first direction in plan view, a transistor electrically connected to the wiring, and a capacitor electrically connected to the wiring;
a first connection portion electrically connecting the first electrode and the second substrate; and
a second connection portion electrically connecting the second electrode and the second substrate.
   (2)

The semiconductor device according to (1), in which the semiconductor element is a light emitting element.

(3)

The semiconductor device according to (1), in which the second electrode has a shape surrounding the first electrode in plan view.

(4)

The semiconductor device according to (1), in which the second electrode has a rectangular shape in plan view.

(5)

The semiconductor device according to (1), in which the transistor and the capacitor are connected in series by the wiring.

(6)

The semiconductor device according to (1), in which the transistor functions as a switch that drives the semiconductor element.

(7)

The semiconductor device according to (1), in which the capacitor is provided in the second direction of the wiring in plan view.

(8)

The semiconductor device according to (1), in which
the second substrate further includes
a first pad electrically connected to the first connection portion and the transistor, and
a second pad electrically connected to the second connection portion and the capacitor.
   (9)

The semiconductor device according to (1), in which
the first substrate further includes a first semiconductor substrate containing gallium and arsenic, and
the second substrate further includes a second semiconductor substrate containing silicon.
   (10)

The semiconductor device according to (1), in which a current in the second electrode flows parallel to the first direction in plan view.

(11)

The semiconductor device according to (10), in which the current in the second electrode flows on a straight line connecting the first connection portion and the second connection portion in plan view.

(12)

The semiconductor device according to (1), in which a current in the wiring flows in parallel to the second direction in plan view.

(13)

The semiconductor device according to (12), in which the current in the wiring flows along a side surface of the wiring in plan view.

(14)

The semiconductor device according to (1), in which an angle between the first direction and the second direction is 5 degrees or less.

(15)

The semiconductor device according to (1), in which the capacitor is provided at a position lower than the first and second connection portions.

(16)

The semiconductor device according to (1), in which
the second substrate further includes a semiconductor substrate, an insulating film provided on the semiconductor substrate, and third and fourth electrodes provided in the insulating film, and
the capacitor includes the third and fourth electrodes.
   (17)

The semiconductor device according to (1), in which
the second substrate further includes a semiconductor substrate, and
the capacitor is a mounted component provided on the semiconductor substrate.
   (18)

The semiconductor device according to (1), in which a distance between a straight line connecting the first connection portion and the second connection portion and a side surface of the wiring is equal to or less than a width of the second electrode in plan view.

(19)

The semiconductor device according to (1), in which a distance between a straight line connecting the first connection portion and the second connection portion and a side surface of the wiring is equal to or less than a pitch between a plurality of the semiconductor elements in a third direction perpendicular to the first direction in plan view.

(20)

A distance measuring device including:
a light emitting unit that includes a light emitting element that generates light and irradiates a subject with the light from the light emitting element;
a light receiving unit that receives light reflected from the subject; and
a distance measuring unit that measures a distance to the subject on the basis of the light received by the light receiving unit, in which
the light emitting unit includes
a first substrate including a semiconductor element, a first electrode provided on the semiconductor element, and a second electrode extending in a first direction in plan view,
a second substrate including a wiring extending in a second direction parallel to the first direction in plan view, a transistor electrically connected to the wiring, and a capacitor electrically connected to the wiring,
a first connection portion electrically connecting the first electrode and the second substrate, and
a second connection portion electrically connecting the second electrode and the second substrate.

### REFERENCE SIGNS LIST

1 Distance measuring device
1a Light emitting device
2 Light emitting unit
2a Light emitting element
3 Drive unit
4 Power supply circuit
5 Light-emitting side optical system
6 Light-receiving side optical system
7 Light receiving unit
8 Signal processing unit
9 Control unit
9a Distance measuring unit
10 Temperature detection unit
11 LD chip
12 LDD substrate
13 Mounting substrate
14 Heat dissipation substrate
15 Correction lens holding unit
16 Correction lens
17 Wiring
18 Bump
21 Substrate
22 Laminated film
23 Light emitting element
24 Anode electrode
25 Cathode electrode
31 Substrate
32 Connection pad
33 Plug
34 Wiring
35 Interlayer insulating film
41 Electrode
41a Common portion
41b Tip portion
42 Electrode
42a Common portion
42b Tip portion
43 Gate insulating film
44 Gate electrode
45 Diffusion layer
46 Diffusion layer

1. A semiconductor device comprising:
a first substrate including a semiconductor element, a first electrode provided on the semiconductor element, and a second electrode extending in a first direction in plan view;
a second substrate including a wiring extending in a second direction parallel to the first direction in plan view, a transistor electrically connected to the wiring, and a capacitor electrically connected to the wiring;
a first connection portion electrically connecting the first electrode and the second substrate; and
a second connection portion electrically connecting the second electrode and the second substrate.

2. The semiconductor device according to claim 1, wherein the semiconductor element is a light emitting element.

3. The semiconductor device according to claim 1, wherein the second electrode has a shape surrounding the first electrode in plan view.

4. The semiconductor device according to claim 1, wherein the second electrode has a rectangular shape in plan view.

5. The semiconductor device according to claim 1, wherein the transistor and the capacitor are connected in series by the wiring.

6. The semiconductor device according to claim 1, wherein the transistor functions as a switch that drives the semiconductor element.

7. The semiconductor device according to claim 1, wherein the capacitor is provided in the second direction of the wiring in plan view.

8. The semiconductor device according to claim 1, wherein
the second substrate further includes
a first pad electrically connected to the first connection portion and the transistor, and
a second pad electrically connected to the second connection portion and the capacitor.

9. The semiconductor device according to claim 1, wherein
the first substrate further includes a first semiconductor substrate containing gallium and arsenic, and
the second substrate further includes a second semiconductor substrate containing silicon.

10. The semiconductor device according to claim 1, wherein a current in the second electrode flows parallel to the first direction in plan view.

11. The semiconductor device according to claim 10, wherein the current in the second electrode flows on a straight line connecting the first connection portion and the second connection portion in plan view.

12. The semiconductor device according to claim 1, wherein a current in the wiring flows in parallel to the second direction in plan view.

13. The semiconductor device according to claim 12, wherein the current in the wiring flows along a side surface of the wiring in plan view.

14. The semiconductor device according to claim 1, wherein an angle between the first direction and the second direction is 5 degrees or less.

15. The semiconductor device according to claim 1, wherein the capacitor is provided at a position lower than the first and second connection portions.

16. The semiconductor device according to claim 1, wherein
the second substrate further includes a semiconductor substrate, an insulating film provided on the semiconductor substrate, and third and fourth electrodes provided in the insulating film, and
the capacitor includes the third and fourth electrodes.

17. The semiconductor device according to claim 1, wherein
the second substrate further includes a semiconductor substrate, and
the capacitor is a mounted component provided on the semiconductor substrate.

18. The semiconductor device according to claim 1, wherein a distance between a straight line connecting the first connection portion and the second connection portion and a side surface of the wiring is equal to or less than a width of the second electrode in plan view.

19. The semiconductor device according to claim 1, wherein a distance between a straight line connecting the first connection portion and the second connection portion and a side surface of the wiring is equal to or less than a pitch between a plurality of the semiconductor elements in a third direction perpendicular to the first direction in plan view.

20. A distance measuring device comprising:
a light emitting unit that includes a light emitting element that generates light and irradiates a subject with the light from the light emitting element;
a light receiving unit that receives light reflected from the subject; and
a distance measuring unit that measures a distance to the subject on a basis of the light received by the light receiving unit, wherein
the light emitting unit includes
a first substrate including a semiconductor element, a first electrode provided on the semiconductor element, and a second electrode extending in a first direction in plan view,
a second substrate including a wiring extending in a second direction parallel to the first direction in plan view, a transistor electrically connected to the wiring, and a capacitor electrically connected to the wiring,
a first connection portion electrically connecting the first electrode and the second substrate, and
a second connection portion electrically connecting the second electrode and the second substrate.
